(19) United States
(12) Patent Application Publication
(10) Pub. No.: US 2007/0170461 A1
(43) Pub. Date: Jul. 26, 2007

(54) Gallium nitride-based compound semiconductor light-emitting device

(76) Inventor: Koji Kamei, Ichihara-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 10/589,611

(22) PCT Filed: Feb. 22, 2005
(86) PCT No.: PCT/JP05/03255

§ 371 Date: Aug. 16, 2006

(30) Foreign Application Priority Data
Feb. 24, 2004 (JP) 2004-048538

(51) Int. Cl. H01L 29/74

(52) U.S. Cl. 257/133

(57) ABSTRACT

An object of the present invention is to provide a gallium nitride compound semiconductor light-emitting device having a positive electrode that exhibits low contact resistance with a p-type gallium nitride compound semiconductor layer and that can be fabricated with high productivity. The inventive gallium nitride compound semiconductor light-emitting device includes a substrate, an n-type semiconductor layer, a light-emitting layer, a p-type semiconductor layer, a negative electrode provided in contact with the n-type semiconductor layer, and a positive electrode provided in contact with the p-type semiconductor layer, the layers being successively provided atop the substrate in this order and being composed of a gallium nitride compound semiconductor, wherein the positive electrode includes at least a contact metal layer which is in contact with the p-type semiconductor layer, the contact metal layer comprises at least one metal selected from the group consisting of Pt, Ir, Rh, Pd, Ru, Re, and Os, or an alloy containing said at least one metal, and the surface portion of the p-type semiconductor layer on the positive electrode side includes a positive-electrode-metal-containing layer that contains at least one metal selected from the group consisting of Pt, Ir, Rh, Pd, Ru, Re, and Os.

### CROSS REFERENCE TO RELATED APPLICATION

This application is an application filed under 35 U.S.C. §111(a) claiming benefit, pursuant to 35 U.S.C. §119(e)(1), of the filing date of the Provisional Application No. 60/549,443 filed on Mar. 3, 2004, pursuant to 35 U.S.C. §111(b).

### TECHNICAL FIELD

The present invention relates to a gallium nitride compound semiconductor light-emitting device and, more particularly, to a flip-chip-type gallium nitride compound semiconductor light-emitting device having a positive electrode that exhibits excellent characteristics and can be fabricated with high productivity.

### BACKGROUND ART

In recent years, gallium nitride compound semiconductors represented by the formula AlₓGa_{y}In_{1-x-y}N (0≦x<1, 0≦y<1, x+y <1) have become of interest as materials for producing a light-emitting diode (LED) which emits ultraviolet to blue light, or green light. Through employment of such a compound semiconductor, ultraviolet light, blue light, or green light of high emission intensity can be obtained; such high-intensity light has conventionally been difficult to attain. Unlike the case of a GaAs light-emitting device, such a gallium nitride compound semiconductor is generally grown on a sapphire substrate (i.e., an insulating substrate); hence, an electrode cannot be provided on the back surface of the substrate. Therefore, both a negative electrode and a positive electrode must be provided on semiconductor layers formed through crystal growth on the substrate.

In the case of the gallium nitride compound semiconductor device, the sapphire substrate is transparent with respect to emitted light. Therefore, attention is drawn to a flip-chip-type light-emitting device, which is configured by mounting the semiconductor device on a lead frame such that the electrodes face the frame, whereby emitted light is extracted through the sapphire substrate.

FIG. 1 is a schematic representation showing a general structure of a flip-chip-type light-emitting device. Specifically, the light-emitting device includes a substrate 1, a buffer layer 2, an n-type semiconductor layer 3, a light-emitting layer 4, and a p-type semiconductor layer 5, the layers being formed atop the substrate through crystal growth. A portion of the light-emitting layer 4 and a portion of the p-type semiconductor layer 5 are removed through etching, thereby exposing a portion of the n-type semiconductor layer 3 to the outside. A positive electrode 10 is formed on the p-type semiconductor layer 5, and a negative electrode 20 is formed on the exposed portion of the n-type semiconductor layer 3. The light-emitting device is mounted on, for example, a lead frame such that the electrodes face the frame, followed by bonding. Therefore, the light emitted from the light-emitting layer 4 is extracted through the substrate 1. In this light-emitting device, in order to attain efficient extraction of light, the positive electrode 10 is formed of a reflective metal, and is provided so as to cover the majority of the p-type semiconductor layer 5, whereby the light emitted from the light-emitting layer toward the positive electrode is reflected by the positive electrode 10, and is also extracted through the substrate 1.

Therefore, the positive electrode is required to be formed from a material exhibiting low contact resistance and high reflectance. One widely known technique for attaining low contact resistance includes forming a contact metal layer on a p-type semiconductor layer from a material such as Au/Ni and alloying the metals so as to form a transparent contact metal layer. Although the technique is suitable for attaining low contact resistance, the formed contact metal layer exhibits poor light transmittance, and the electrode including the contact metal layer exhibits low reflectance.

Meanwhile, a contact metal layer exhibiting both low contact resistance and high reflectance may be produced from a metal exhibiting high work function, such as Pt. In fact, Japanese Patent Application Laid-Open (kokai) Nos. 2000-36619, 2000-183400, etc. disclose that a metal such as Pt is directly vapor-deposited as a contact metal layer on a p-type semiconductor layer. However, the formed metal contact layer exhibits a high contact resistance compared with that attained through the Au/Ni alloying technique.

Japanese Patent No. 3,365,607 discloses that, in an attempt to lower contact resistance, a contact metal layer to be in contact with a p-type semiconductor layer is formed of a layer containing a Pt-group metal and Ga. Specifically, Pt and Ga are simultaneously vapor-deposited on a p-type semiconductor layer to form a layer (thickness: 20 nm) and, subsequently, Pt is further vapor-deposited (thickness: 100 nm). Alternatively, Pt is directly vapor-deposited (thickness: 100 nm) on a p-type semiconductor layer, followed by annealing (600 to 900° C.). However, the technique has a drawback, in that the simultaneous vapor deposition of Ga and another metal or the annealing involved in the technique lowers the productivity.

### DISCLOSURE OF INVENTION

An object of the present invention is to provide a gallium nitride compound semiconductor light-emitting device having a positive electrode that exhibits low contact resistance with a p-type gallium nitride compound semiconductor layer and that can be fabricated with high productivity.

The present invention provides the following.
(1) A gallium nitride compound semiconductor light-emitting device including a substrate, an n-type semiconductor layer, a light-emitting layer, a p-type semiconductor layer, a negative electrode provided in contact with the n-type semiconductor layer, and a positive electrode provided in contact with the p-type semiconductor layer, the layers being successively provided atop the substrate in this order and being composed of a gallium nitride compound semiconductor, wherein

the positive electrode includes at least a contact metal layer which is in contact with the p-type semiconductor layer,

the contact metal layer comprises at least one metal selected from the group consisting of Pt, Ir, Rh, Pd, Ru, Re, and Os, or an alloy containing said at least one metal, and

the surface portion of the p-type semiconductor layer on the positive electrode side includes a positive-electrode-metal-containing layer that contains at least one metal selected from the group consisting of Pt, Ir, Rh, Pd, Ru, Re, and Os.
(2) A gallium nitride compound semiconductor light-emitting device according to (1) above, wherein the positive-electrode-metal-containing layer has a thickness of 0.1 to 10 nm.
(3) A gallium nitride compound semiconductor light-emitting device according to (1) or (2) above, wherein the positive-electrode-metal-containing layer contains at least one metal selected from the group consisting of Pt, Ir, Rh, Pd, Ru, Re, and Os at a concentration of 0.01 to 30 at. % with respect to the total amount of metal atoms contained in the positive-electrode-metal-containing layer.
(4) A gallium nitride compound semiconductor light-emitting device according to any one of (1) to (3) above, wherein the positive electrode includes a reflecting layer on the contact metal layer, the reflecting layer comprising at least one metal selected from the group consisting of Pt, Ir, Rh, Pd, Ru, Re, Os, and Ag, or an alloy containing said at least one metal.
(5) A gallium nitride compound semiconductor light-emitting device according to (4) above, wherein the reflecting layer has a columnar crystal structure.
(6) A gallium nitride compound semiconductor light-emitting device according to (4) or (5) above, wherein the contact metal layer has a thickness of 1 to 30 nm.
(7) A gallium nitride compound semiconductor light-emitting device according to any one of (4) to (6) above, wherein the reflecting layer has a thickness of 30 to 500 nm.
(8) A gallium nitride compound semiconductor light-emitting device according to any one of (1) to (7) above, wherein the surface portion of the contact metal layer on the p-type semiconductor layer side includes a semiconductor-metal-containing layer that contains a Group III metal.
(9) A gallium nitride compound semiconductor light-emitting device according to (8) above, wherein the semiconductor-metal-containing layer further contains a nitrogen atom.
(10) A gallium nitride compound semiconductor light-emitting device according to (8) or (9) above, wherein the semiconductor-metal-containing layer has a thickness of 0.1 to 3 nm.
(11) A gallium nitride compound semiconductor light-emitting device according to any one of (8) to (10) above, wherein the semiconductor-metal-containing layer contains a Group III metal at a concentration of 0.1 to 50 at. % with respect to the total amount of metal atoms contained in the semiconductor-metal-containing layer.
(12) A gallium nitride compound semiconductor light-emitting device according to any one of (1) to (11) above, wherein the contact metal layer comprises Pt.
(13) A gallium nitride compound semiconductor light-emitting device according to (12) above, wherein the contact metal layer has a Pt (222) plane spacing of 1.130 Å or less.
(14) A gallium nitride compound semiconductor light-emitting device according to any one of (1) to (13) above, wherein the contact metal layer is formed through RF discharge sputtering.
(15) A gallium nitride compound semiconductor light-emitting device according to any one of (4) to (13) above, wherein the contact metal layer is formed through RF discharge sputtering, and the reflecting layer is formed through DC discharge sputtering.
(16) A method for producing a gallium nitride compound semiconductor light-emitting device according to any one of (1) to (15) above, wherein the gallium nitride compound semiconductor light-emitting device is maintained at a temperature of 350° C. or less after a step of forming the contact metal layer.

In the gallium nitride compound semiconductor light-emitting device of the present invention, the surface portion of the p-type semiconductor layer on the positive electrode side includes a positive-electrode-metal-containing layer that contains a metal forming the contact metal layer. Thus, contact resistance between the positive electrode and the p-type semiconductor layer can be lowered.

In the light-emitting device of the present invention, the surface portion of the positive electrode contact metal layer on the semiconductor layer side includes a semiconductor-metal-containing layer that contains a Group III metal forming the semiconductor layer. Thus, contact resistance can be further lowered.

In addition, as the positive electrode contact metal layer is formed through RF discharge sputtering, the positive-electrode-metal-containing layer and the semiconductor-metal-containing layer can be formed without annealing, resulting in an enhancement of productivity.

### BRIEF DESCRIPTION OF DRAWINGS

FIG. 1 is a schematic representation showing a general structure of a conventional flip-chip-type compound semiconductor light-emitting device.

FIG. 2 is a schematic representation showing a general structure of an exemplary flip-chip-type compound semiconductor light-emitting device according to the present invention.

FIG. 3 is an exemplary chart showing results of the EDS analysis of a cross-section TEM image of a contact metal layer of the compound semiconductor light-emitting device fabricated in Example 1.

FIG. 4 is an exemplary chart showing results of the EDS analysis of a cross-section TEM image of a p-type semiconductor layer of the compound semiconductor light-emitting device fabricated in Example 1.

FIG. 5 is an exemplary chart showing results of the SIMS analysis of a positive electrode/a p-type contact layer of the compound semiconductor light-emitting device fabricated in Example 5.

FIG. 6 is an exemplary chart showing results of the EDS analysis of a cross-section TEM image of a contact metal layer of the compound semiconductor light-emitting device fabricated in Example 5.

FIG. 7 is an exemplary cross-section TEM photograph of a positive electrode/a p-type contact layer of the compound semiconductor light-emitting device fabricated in Example 5.

### BEST MODES FOR CARRYING OUT THE INVENTION

In the present invention, no particular limitation is imposed on the gallium nitride compound semiconductor layers stacked on a substrate, and the semiconductor stacked layers may have a conventionally known structure as shown in FIG. 1; i.e., a laminate including a buffer layer 2, an n-type semiconductor layer 3, a light-emitting layer 4, and a p-type semiconductor layer 5, the layers being formed atop a substrate 1 through crystal growth. No particular limitation is imposed on the species of the substrate, and conventionally known substrates such as sapphire and SiC may be employed. A variety of gallium nitride compound semiconductors represented by formula: AlₓIn_{y}Ga_{1-x-y}N (0≦x<1; 0≦y<1; x+y<1) are known. No particular limitation is imposed on the gallium nitride compound semiconductor employed in the present invention, and gallium nitride compound semiconductors represented by the formula: AlₓIn_{y}Ga_{1-x-y}N (0≦x≦1; 0≦y<1; x+y<1) may also be employed.

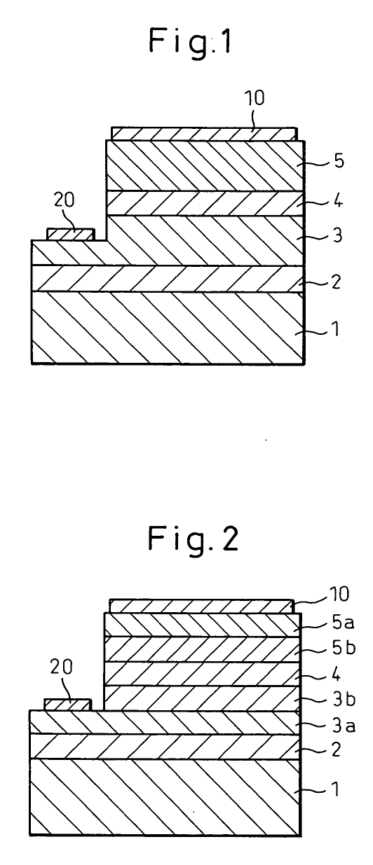

For example, the gallium nitride compound semiconductor laminate may be a stacked structure shown in FIG. 2, which includes a buffer layer 2 formed of an AlN layer, a contact layer 3a formed of an n-type GaN layer, a lower cladding layer 3b formed of an n-type GaN layer, a light-emitting layer 4 formed of an InGaN layer, an upper cladding layer 5b formed of a p-type AlGaN layer, and a contact layer 5a formed of a p-type GaN layer, the layers 2 through 5a being successively formed atop a sapphire substrate 1.

A portion of each of the following layers: the contact layer 5a, the upper cladding layer 5b, the light-emitting layer 4, and the lower cladding layer 3b, which layers constitute the aforementioned gallium nitride compound semiconductor laminate, is removed through etching and, subsequently, a conventional negative electrode 20 (e.g., Ti/Au) is provided on a portion of the contact layer 3a. A positive electrode 10 is provided on the contact layer 5a.

According to the present invention, the positive electrode 10 essentially includes a contact metal layer that is in contact with a p-type semiconductor layer. A reflecting layer may be formed on the contact metal layer. If the contact metal layer exhibits sufficient reflectance, the contact metal layer also serves as a reflecting layer. However, preferably, a contact metal layer for attaining low contact resistance and a reflecting layer for attaining high reflectance are provided independently from each other. In the case where a reflecting layer is provided, the contact metal layer is required to exhibit low contact resistance and high light-transmittance. On the top of the positive electrode, a bonding pad layer for establishing electric contact between the positive electrode and a circuit substrate, a lead frame, etc. is generally provided.

In order to attain low contact resistance, the contact metal layer is preferably produced from a metal exhibiting high work function; i.e., at least one metal selected from the group consisting of Pt, Ir, Rh, Pd, Ru, Re, and Os, or an alloy containing said at least one metal. The metal is more preferably Pt, Ir, Rh, or Ru, with Pt being particularly preferred.

The contact metal layer preferably has a thickness of 1 nm or more, so as to consistently attain low contact resistance, more preferably 2 nm or more, particularly preferably 3 nm or more. From the viewpoint of sufficient light transmittance, the thickness is preferably 30 nm or less, more preferably 20 nm or less, particularly preferably 10 nm or less.

The surface of the p-type semiconductor layer on the positive electrode side includes a positive-electrode-metal-containing layer that contains a metal forming the aforementioned contact metal layer. Through employment of the structure, contact resistance between the positive electrode and the p-type semiconductor layer can be lowered.

In the present invention, the term “positive-electrode-metal-containing layer” refers to a layer which is present in a p-type semiconductor layer and which contains a metal forming the contact metal layer.

The positive-electrode-metal-containing layer preferably has a thickness of 0.1 to 10 nm. When the thickness is less than 0.1 nm or in excess of 10 nm, low contact resistance is difficult to attain. More preferably, the thickness is 1 to 8 nm, in order to attain further lower the contact resistance. Table 1 shows the relationship between the thickness of the positive-electrode-metal-containing layer and the forward voltage at a current of 20 mA.

TABLE 1

| Thickness of Positive- | |
|---|---|
| electrode-metal-containing | |
| layer | Forward Voltage |
| nm | V |
| 0.1 | 4 |
| 1 | 3.3 |
| 5 | 3.2 |
| 8 | 3.3 |
| 10 | 3.6 |

The positive-electrode-metal-containing layer preferably contains a metal forming the contact metal layer at a concentration of 0.01 to 30 at. % with respect to the total amount of metal atoms contained in the positive-electrode-metal-containing layer. When the concentration is less than 0.01 at. %, low contact resistance is difficult to attain, whereas when the concentration is in excess of 30 at. %, the crystallinity of the semiconductor may be impaired. Thus, the concentration is preferably 1 to 20 at. %. The concentration varies in the positive-electrode-metal-containing layer and the concentration at the interface in contact with the contact metal layer is higher. Notably, the positive-electrode-metal-containing layer may contain a metal forming a reflecting layer. In this case, the metal concentration is derived from the sum of contact-metal-layer-forming metals and reflecting-layer-forming metals.

The thickness of the positive-electrode-metal-containing layer and the positive-electrode-forming metal content of the layer can be determined through EDS analysis of a cross-section TEM image, which is well known to those skilled in the art. Specifically, a plurality of cross-section TEM images (e.g., five images) of the p-type semiconductor layer are observed from the top surface (on the positive electrode side) thereof to the bottom surface thereof in the thickness direction, and the observed images are analyzed through EDS. From each EDS chart, the species and the amount of metal(s) contained in the layer can be determined. In the case where the five images are insufficient to determine the thickness of the layer, additional images are captured and analyzed.

Incorporation of a semiconductor-metal-containing layer that contains a metal forming the semiconductor into the surface portion of the contact metal layer on the semiconductor side is also preferred, because contact resistance between the positive electrode and the p-type semiconductor layer is further lowered. In the present invention, the term “semiconductor-metal-containing layer” refers to a layer which is present in the contact metal layer and which contains a metal forming the semiconductor.

The semiconductor-metal-containing layer preferably has a thickness of 0.1 to 3 nm. When the thickness is less than 0.1 nm, contact resistance is not remarkably improved whereas, when the thickness is in excess of 3 nm, light transmittance is lowered. More preferably, the thickness is 1 to 3 nm. Table 2 shows the relationship between the thickness of the semiconductor-metal-containing layer and the forward voltage at a current of 20 mA.

TABLE 2

| Thickness of Semiconductor- | |
|---|---|
| metal-containing layer | Forward Voltage |
| nm | V |
| 0.1 | 3.9 |
| 1 | 3.2 |
| 2 | 3.3 |
| 3 | 3.3 |
| 5 | 3.3 |

The semiconductor-metal-containing layer preferably contains a semiconductor-forming metal at a concentration of 0.1 to 50 at. % with respect to the total amount of metal atoms contained in the semiconductor-metal-containing layer. When the concentration is less than 0.1%, contact resistance is not remarkably improved, whereas when the concentration is in excess of 50 at. %, light transmittance may be lowered. More preferably, the concentration is 1 to 20 at. %.

Similar to the positive-electrode-containing layer, the thickness of the semiconductor-metal-containing layer and the semiconductor-forming metal content can be determined through EDS analysis of a cross-section TEM image.

The reflecting layer may be formed from a high-reflectance metal; e.g., at least one metal selected from the group consisting of Pt, Ir, Rh, Pd, Ru, Re, Os, and Ag, or an alloy containing said at least one metal. The reflecting layer preferably has a thickness of 30 nm or more. When the thickness is less than 30 nm, it is difficult to form a high-reflectance electrode uniformly on the entire surface. Thus, the thickness is more preferably 50 nm or more. From the viewpoint of production cost, the thickness is preferably 500 nm or less.

No particular limitation is imposed on the material and structure of the bonding pad layer, and a variety of conventionally known structures formed of a material such as Au, Al, Ni, and Cu may be employed. The bonding pad layer preferably has a thickness of 100 to 1,000 nm. In consideration of the characteristics of the bonding pad layer, the greater the thickness of the layer, the more enhanced the bonding performance. Thus, the thickness is preferably 300 nm or more. However, from the viewpoint of production cost, the thickness is preferably 500 nm or less.

Next, the methods for forming a contact metal layer, a positive-electrode-metal-containing layer, and a semiconductor-metal-containing layer will be described.

The contact metal layer is preferably formed on a p-type semiconductor layer through sputtering based on RF discharge. It has been elucidated that an electrode exhibiting low contact resistance can be formed through RF discharge sputtering rather than through vapor deposition or DC discharge sputtering.

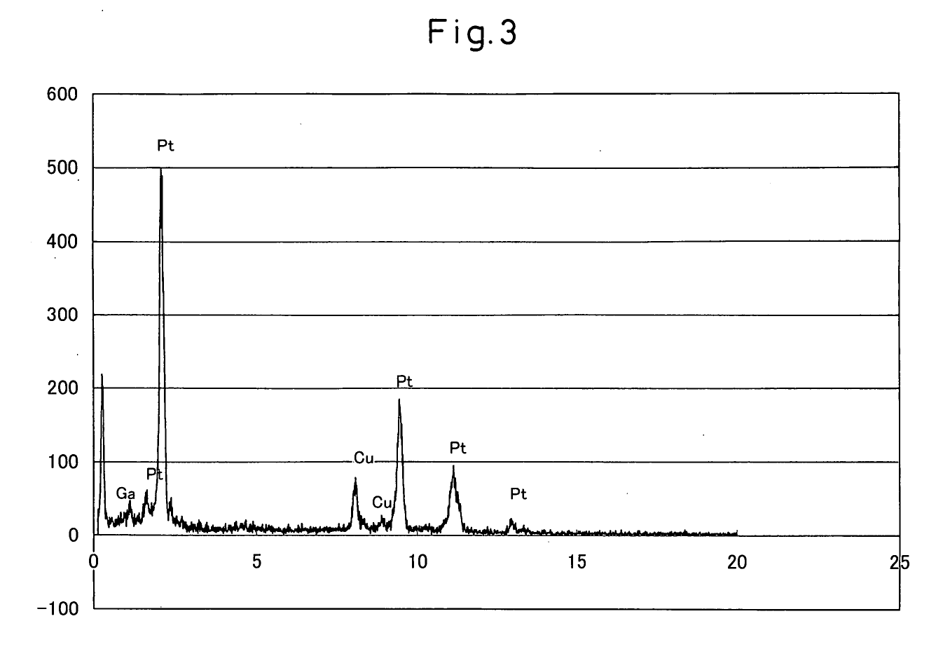

In film formation through RF discharge sputtering, sputtered atoms deposited on the p-type semiconductor layer gain energy through an ion-assisting effect. Thus, diffusion of the sputtered atoms in the surface portion of p-type semiconductor (e.g., Mg-doped p-GaN) is considered to be promoted. In addition, atoms forming the top surface of the p-type semiconductor are imparted with energy during film formation. Thus, diffusion of a semiconductor material (e.g., Ga) in the contact metal layer is considered to be promoted. Through EDS analysis of a cross-section TEM image of the contact metal layer (i.e., film formed on the p-GaN layer through RF sputtering), a portion containing both Ga originating from the semiconductor and Pt forming the contact metal layer (i.e., a semiconductor-metal-containing layer) was observed (see FIG. 3; analysis results of a contact metal layer obtained in Example 1 of the present invention).

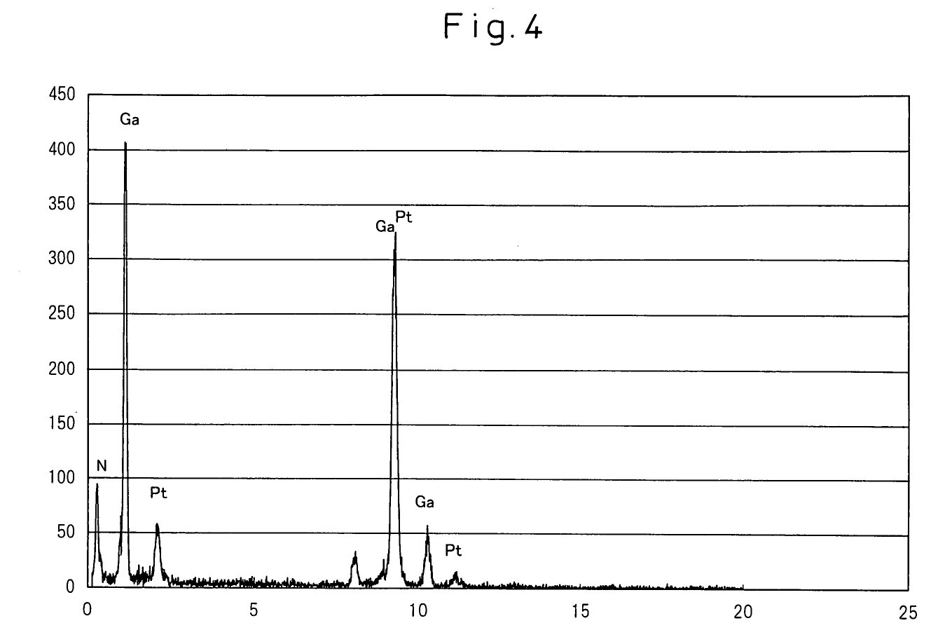

In the semiconductor layer, a portion containing Ga, N, and Pt (i.e., a positive-electrode-metal-containing layer) was observed through EDS analysis of a cross-section section TEM image (see FIG. 4; analysis results of a p-type semiconductor layer obtained in Example 1 of the present invention).

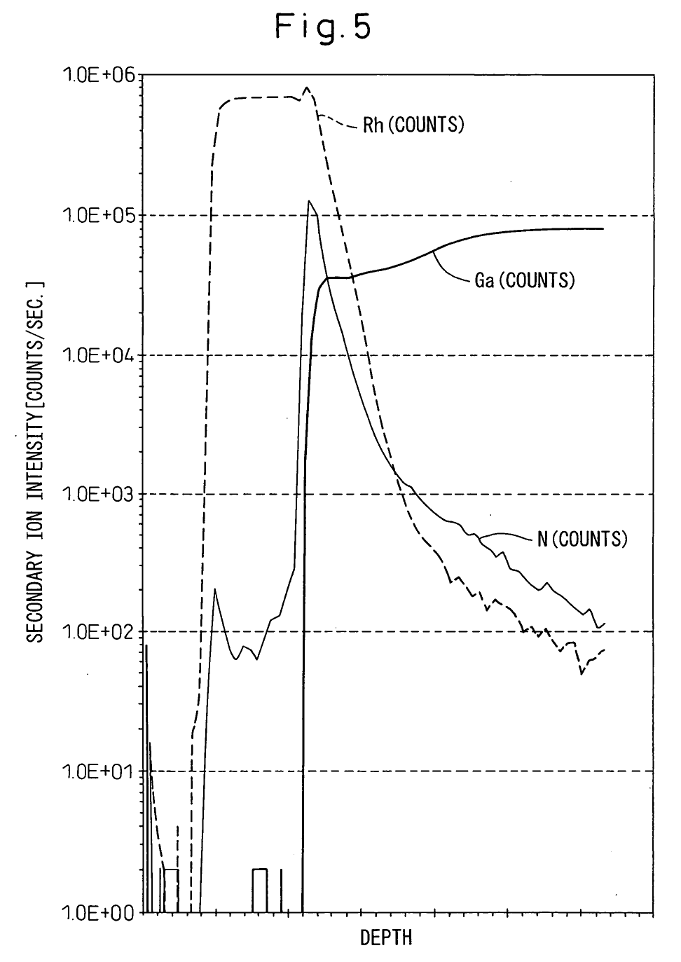

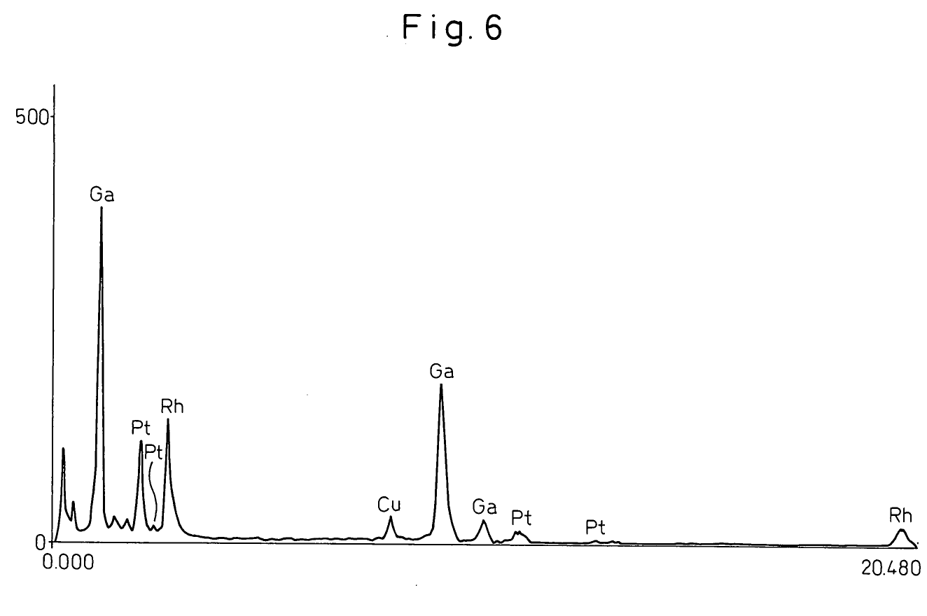

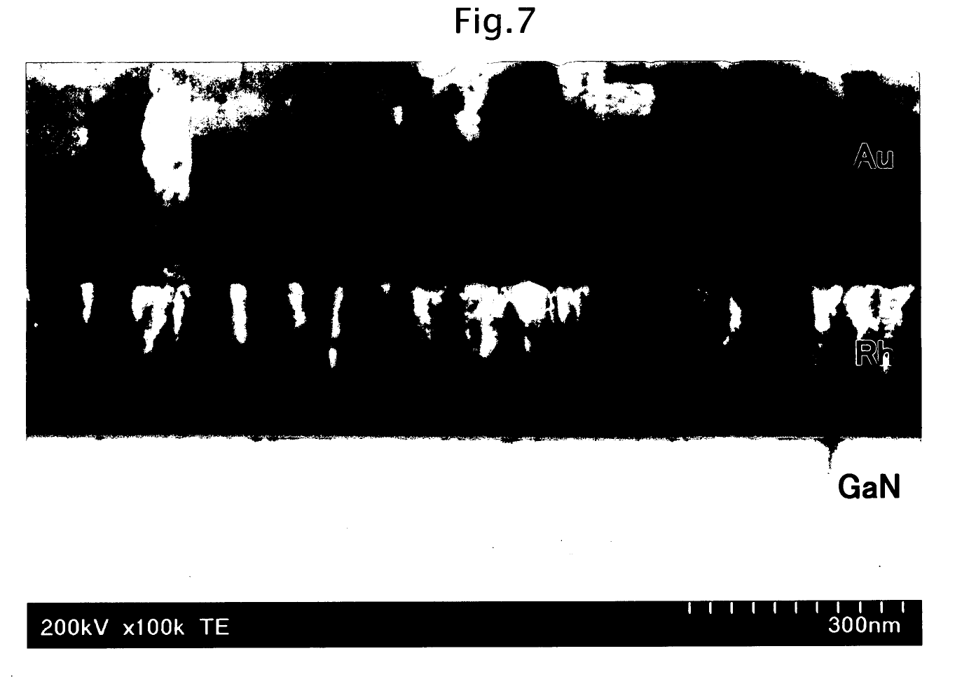

In the EDS analysis of a cross-section TEM image, the presence of N in the semiconductor-metal-containing layer could not be confirmed. In a SIMS analysis, however, presence of N in the semiconductor-metal-containing layer could be confirmed. A light-emitting device obtained in Example 5 was analyzed through the SIMS analysis from a positive electrode side. FIG. 5 is an exemplary chart plotting a secondary ion intensity of Rh, Ga and N against a depth. N combined with Rh could be confirmed. Also, FIG. 6 is an exemplary chart showing results of the EDS analysis of a cross-section TEM image of a contact metal layer of the light-emitting device obtained in Example 5. In this analysis, N was below the detection limit and presence of N could not be confirmed.

The film formed through RF discharge sputtering is different in terms of, for example, crystallinity from the film formed through DC discharge sputtering. From a cross-section TEM photographs, a columnar crystal structure is observed in DC film, indicating that the DC film is a dense film. In contrast, no columnar crystal structure is observed in RF film. FIG. 7 is a cross-section TEM photograph (magnification=200,000) of the light-emitting device obtained in Example 5. It is found that the Rh reflecting layer formed through DC discharge sputtering has a columnar crystal structure. At this magnification, the Pt contact metal layer could not be discriminated.

As shown in Table 3 , Pt(222) plane lattice spacing determined through an X-ray analysis was found to be smaller in DC film than in RF film.

TABLE 3
Pt(222) plane spacing

| Contact metal layer | Sputtering | Pt (222) plane spacing |
|---|---|---|
| Pt | DC | 1.138 |
| Pt | RF | 1.128 |

When RF discharge sputtering is employed, in an initial stage, the contact resistance of the formed film is lowered. However, when the film thickness increases, because the film density is small, reflectance of the film is lower than the film formed through DC discharge sputtering. Thus, in a preferred mode, a contact metal thin layer having a limited thickness is formed through RF discharge sputtering, so as to exhibit low contact resistance and enhanced light transmittance, and subsequently, a reflecting layer is formed thereon through DC discharge.

Table 4 shows the relationship between the thickness of contact metal films formed through RF discharge sputtering and the light transmittance of the films, along with comparison with conventional thin film formed through alloying of Au/Ni. As is clear from Table 4, a decrease in film thickness results in high transmittance.

TABLE 4
Light transmittance of metal thin film
(@ = 450 nm)

| | Film thickness | Transmittance |
|---|---|---|
| Au/Ni, after annealing | 15 nm | About 70% |
| Pt RF film | 2.5 nm | About 75% |
| ″ | 5.0 nm | About 50% |

As described above, by forming a contact metal layer through RF sputtering, the semiconductor-metal-containing layer and the positive-electrode-metal-containing layer of the present invention is successfully formed. According to the technique, annealing after formation of the contact metal layer can be eliminated. If annealing is performed at a temperature higher than 350° C., diffusion of Pt and Ga is promoted, thereby reducing the crystallinity of semiconductor, possibly resulting in impairment of electric characteristics.

In the semiconductor-metal-containing layer and in the positive-electrode-metal-containing layer, the metal originating from the positive electrode material, the metal (e.g., Ga) originating from the semiconductor material, and N are considered to be present in the form of compound, alloy, or simple mixture. In any case, by the mediation of the above layers, the interface between the contact metal layer and the p-type semiconductor layer becomes so unclear that the interface can no longer be defined, thereby attaining low electric resistance.

By using the above-mentioned method, even if there is a certain high measure of a hydrogen concentration in the p-type contact layer, an ohmic contact between the p-type contact layer and the positive electrode is attained. Generally, it is considered that a p-type dopant Mg is combined with a hydrogen in the p-type contact layer, so as not to function as a dopant. Therefore, when the hydrogen concentration in the p-type contact layer is lower, the ohmic contact is attained more easily. In the inventive light-emitting device, however, even if the hydrogen concentration in the p-type contact layer is 10¹⁹/cm⁻³ or more, the ohmic contact is attained.

RF sputtering may be performed by use of a generally known sputtering apparatus under the conditions appropriately selected from those conventionally employed. Specifically, a structure including a substrate and a gallium nitride compound semiconductor layer stacked on the substrate is placed in a chamber, and the substrate temperature is controlled to fall within a range of room temperature to 500° C. Although no particular heating of the substrate is required, the substrate may be appropriately heated in order to promote diffusion of a contact-metal-layer-forming metal and a semiconductor-forming metal. The chamber is evacuated to a vacuum of 10⁻⁴ to 10⁻⁷ Pa. Examples of employable sputtering gases include He, Ne, Ar, Kr, and Xe. Of these, Ar is preferred from the viewpoint of availability. Any one of them is introduced to the chamber such that the pressure inside the chamber is controlled to 0.1 to 10 Pa, preferably 0.2 to 5 Pa, and then discharge is started. The input power is preferably 0.2 to 2.0 kW. By controlling discharge time and supplied power, the thickness of the formed layer can be regulated. The sputtering target to be employed preferably has an oxygen content of 10,000 ppm or less, so as to lower the oxygen content of the formed layer, and is more preferably 6,000 ppm or less.

### EXAMPLES

The present invention will next be described in more detail by way of Examples and Comparative Example, which should not be construed as limiting the invention thereto.

Table 5 shows the positive electrode materials and contact metal layer formation conditions employed in the Examples and Comparative Example, and characteristics of the fabricated devices. In the Examples and Comparative Example, the specific contact resistance was determined through the TLM method, and forward voltage and output were determined at a current of 20 mA.

### Example 1

FIG. 2 is a schematic view showing a gallium nitride compound semiconductor light-emitting device produced in the present Example.

The gallium nitride compound semiconductor stacked structure employed for fabricating the light-emitting device was produced through the following procedure: an AlN buffer layer 2 was formed on a sapphire substrate 1; and an n-type GaN contact layer 3a, an n-type GaN lower cladding layer 3b, an InGaN light-emitting layer 4, a p-type AlGaN upper cladding layer 5b, and a p-type GaN contact layer 5a were successively formed atop the buffer layer 2. The contact layer 3a is composed of n-type GaN doped with Si (7×10¹⁸/cm³), the lower cladding layer 3b is composed of n-type GaN doped with Si (5×10¹⁸/cm³), and the light-emitting layer 4, having a single quantum well structure, is composed of In_{0.95}Ga_{0.05}N. The upper cladding layer 5b is composed of p-type Al_{0.25}Ga_{0.75}N doped with Mg (1×10¹⁸/cm³). The contact layer 5a is composed of p-type GaN doped with Mg (5×10¹⁹/cm³). Stacking of these layers was performed by means of MOCVD under typical conditions which are well known in the art.

A positive electrode and a negative electrode were provided on the gallium nitride compound semiconductor stacked structure through the below-described procedure, to thereby fabricate a flip-chip-type gallium nitride compound semiconductor light-emitting device.

(1) Firstly, in order to remove oxide film on the contact layer 5a, the gallium nitride compound semiconductor device was treated in concentrate HCl under boiling for 10 minutes.

Then, a positive electrode was formed on the contact layer 5a through the following procedure.

A resist was uniformly applied onto the entire surface of the contact layer, and a portion of the resist provided on the region where the positive electrode was to be formed was removed through a conventional lithographic technique. The thus-formed structure was immersed in buffered hydrofluoric acid (BHF) at room temperature for one minute, followed by forming a positive electrode in a vacuum sputtering apparatus in the following manner.

The chamber was evacuated to a degree of vacuum of 10⁻⁴ Pa or less. The aforementioned gallium nitride compound semiconductor stacked structure was placed in the chamber, and Ar serving as a sputtering gas was fed into the chamber. After the internal pressure of the chamber was controlled to 3 Pa, RF discharge sputtering was started. Input power was 0.5 kW, and a Pt layer (thickness: 4.0 nm) serving as a contact metal layer was formed. Subsequently, under the same pressure and input power as described above, a Pt reflecting layer (thickness: 200 nm) was formed through DC discharge sputtering. Subsequently, under the same pressure and input power as described above, an Au bonding pad layer (thickness: 300 nm) was formed through DC discharge sputtering. The structure was removed from the sputtering apparatus, and a portion of metallic film other than the positive electrode region was removed along with the resist through a lift-off technique.

(2) An etching mask was formed on the positive electrode through the following procedure. After uniform provision of a resist on the entire surface, a portion of the resist corresponding to a region slightly wider than the positive electrode region was removed through a conventional lithography technique. The structure was placed in a vacuum vapor deposition apparatus, and an Ni layer and a Ti layer were stacked through the electron beam method at thickness of about 50 nm and 300 nm, respectively, under a pressure of 4×10⁻⁴ Pa or lower. Thereafter, a portion of metal film other than the etching mask was removed along with the resist through the lift-off technique. The etching mask serves as a protective layer for protecting the positive electrode from plasma-induced damage during reactive ion dry etching for exposing the contact layer 3.

(3) The contact layer 3a was exposed through the following procedure. Specifically, the semiconductor stacked structure was etched through reactive ion dry etching until the contact layer 3a was exposed, and the resultant stacked structure was removed from the dry etching apparatus. The etching mask formed in (2) above was removed by use of nitric acid and hydrofluoric acid. The dry etching was performed for the purpose of formation of an n-type electrode fabricated in the below-mentioned step.

(4) A negative electrode was formed on the contact layer 3a through the following procedure. After uniform provision of a resist on the entire surface, a portion of the resist corresponding to a negative electrode region of the exposed contact layer 3a was removed through a conventional lithography technique. Ti (thickness: 100 nm) and Au (thickness: 300 nm) were formed through the aforementioned vapor deposition method. The portion of metallic film other than the negative electrode region was removed along with the resist.

(5) A protective film was formed through the following procedure. After uniform provision of a resist on the entire surface, a portion of the resist between the positive electrode and the negative electrode was removed through a conventional lithography technique. SiO₂ film (thickness: 200 nm) was formed through the aforementioned sputtering method. The portion of SiO₂ film other than the protected region was removed along with the resist.

(6) The wafer was cut into pieces, to thereby fabricate the gallium nitride compound semiconductor light-emitting device of the present invention.

The steps of forming the positive and negative electrodes were performed at a temperature of 350° C. or less.

Each of the produced gallium nitride compound semiconductor light-emitting device pieces was mounted on a TO-18, and the device characteristics were determined. The results are shown in Table 3.

Through EDS analysis of cross-section TEM images, the thickness of the semiconductor-metal-containing layer was estimated to be 2.5 nm, and the Ga content (with respect to all metal atoms (Pt+Ga)) of the layer was estimated to 1 to 20 at. %. The thickness of the positive-electrode-metal-containing layer was estimated to be 6.0 nm. In the layer, Pt was found to be present as the positive electrode material. The Pt content (with respect to all metal atoms (Pt+Ga)) of the layer was estimated to 1 to 10 at. %. FIG. 3 is an exemplary chart showing results of the EDS analysis of a cross-section TEM image of a contact metal layer, and FIG. 4 is an exemplary chart showing results of the EDS analysis of a cross-section TEM image of a contact layer 5a.

### Examples 2 to 14

The procedure of Example 1 was repeated, except that the positive electrode material and film formation conditions are varied, to thereby fabricate gallium nitride compound semiconductor light-emitting devices. The device characteristics were also determined. The results are shown in Table 5. With respect to these light-emitting devices, the thickness of the positive-electrode-metal-containing layer was 1 to 8 nm, and the positive electrode metal content was 0.5 to 18%. The thickness of the semiconductor-metal-containing layer was 0.5 to 3 nm, and the Ga content was 1 to 20%. Also, when the light-emitting device obtained in Example 3 was annealed in an RTA furnace in the atmosphere at 400° C. for 10 minutes, the forward voltage went up to 3.8 V.

### Comparative Example

The procedure of Example 2 was repeated, except that the contact metal layer was formed through DC discharge sputtering, to thereby fabricate a gallium nitride compound semiconductor light-emitting device. No positive-electrode-metal-containing layer or semiconductor-metal-containing layer was observed in the fabricated device. Device characteristics thereof are shown in Table 5.

TABLE 5
Conditions employed in Examples and Comparative Example and device characteristic

| | Contact metal layer | | | | | | | | | |
|---|---|---|---|---|---|---|---|---|---|---|
| | | | Film formation | | | | | Specific | Device | |
| | | | conditions | | | | Bonding | contact | characteristic | |
| | | Film | | Pressure/ | | Reflectivity | pad | resistance | Forward | Output/ |
| | Material | formation | Power/W | Pa | Thickness/Å | layer | layer | Ωcm² | voltage/V | mW |
| Comp. Ex. | Pt | DC | 100 | 0.8 | 40 | Pt | Au | 2 × 10⁻¹ | 5 | 6.5 |
| Ex. 1 | Pt | RF | 500 | 3 | 40 | Pt | Au | 4 × 10⁻² | 4.3 | 5.8 |
| Ex. 2 | Pt | RF | 100 | 0.8 | 40 | Pt | Au | 3 × 10⁻² | 4.2 | 5.9 |
| Ex. 3 | Pt | RF | 100 | 3 | 40 | Pt | Au | 5 × 10⁻⁵ | 3.4 | 6 |
| Ex. 4 | Pt | RF | 100 | 3 | 15 | Pt | Au | 5 × 10⁻³ | 4 | 6.3 |
| Ex. 5 | Pt | RF | 100 | 3 | 40 | Rh | Au | 5 × 10⁻⁵ | 3.3 | 6.2 |
| Ex. 6 | Pt | RF | 100 | 3 | 40 | Ir | Au | 5 × 10⁻⁵ | 3.3 | 6.3 |
| Ex. 7 | Pt | RF | 100 | 3 | 40 | Re | Au | 5 × 10⁻⁵ | 3.3 | 6.1 |
| Ex. 8 | Pt | RF | 100 | 3 | 40 | Ru | Au | 5 × 10⁻⁵ | 3.3 | 6.1 |
| Ex. 9 | Pt | RF | 100 | 3 | 40 | Ag | Au | 5 × 10⁻⁵ | 3.3 | 6.6 |
| Ex. 10 | Rh | RF | 100 | 3 | 40 | Pt | Au | 6 × 10⁻⁵ | 3.4 | 6 |
| Ex. 11 | Ir | RF | 100 | 3 | 40 | Pt | Au | 5 × 10⁻⁵ | 3.4 | 6.1 |
| Ex. 12 | Ru | RF | 100 | 3 | 40 | Pt | Au | 7 × 10⁻⁵ | 3.6 | 5.9 |
| Ex. 13 | Re | RF | 100 | 3 | 40 | Pt | Au | 8 × 10⁻⁵ | 3.5 | 5.8 |
| Ex. 14 | Pd | RF | 100 | 3 | 40 | Pt | Au | 9 × 10⁻⁵ | 3.6 | 5.9 |

### INDUSTRIAL APPLICABILITY

The gallium nitride compound semiconductor light-emitting device according to the present invention exhibits excellent characteristics and can be produced at high productivity. Thus, the light-emitting device is useful for producing light-emitting diodes, lamps, etc.

1. A gallium nitride compound semiconductor light-emitting device including a substrate, an n-type semiconductor layer, a light-emitting layer, a p-type semiconductor layer, a negative electrode provided in contact with the n-type semiconductor layer, and a positive electrode provided in contact with the p-type semiconductor layer, the layers being successively provided atop the substrate in this order and being composed of a gallium nitride compound semiconductor, wherein
the positive electrode includes at least a contact metal layer which is in contact with the p-type semiconductor layer,
the contact metal layer comprises at least one metal selected from the group consisting of Pt, Ir, Rh, Pd, Ru, Re, and Os, or an alloy containing said at least one metal, and
the surface portion of the p-type semiconductor layer on the positive electrode side includes a positive-electrode-metal-containing layer that contains at least one metal selected from the group consisting of Pt, Ir, Rh, Pd, Ru, Re, and Os.

2. A gallium nitride compound semiconductor light-emitting device according to claim 1, wherein the positive-electrode-metal-containing layer has a thickness of 0.1 to 10 nm.

3. A gallium nitride compound semiconductor light-emitting device according to claim 1, wherein the positive-electrode-metal-containing layer contains at least one metal selected from the group consisting of Pt, Ir, Rh, Pd, Ru, Re, and Os at a concentration of 0.01 to 30 at. % with respect to the total amount of metal atoms contained in the positive-electrode-metal-containing layer.

4. A gallium nitride compound semiconductor light-emitting device according to claim 1, wherein the positive electrode includes a reflecting layer on the contact metal layer, the reflecting layer comprising at least one metal selected from the group consisting of Pt, Ir, Rh, Pd, Ru, Re, Os, and Ag, or an alloy containing said at least one metal.

5. A gallium nitride compound semiconductor light-emitting device according to claim 4, wherein the reflecting layer has a columnar crystal structure.

6. A gallium nitride compound semiconductor light-emitting device according to claim 4, wherein the contact metal layer has a thickness of 1 to 30 nm.

7. A gallium nitride compound semiconductor light-emitting device according to claim 4, wherein the reflecting layer has a thickness of 30 to 500 nm.

8. A gallium nitride compound semiconductor light-emitting device according to claim 1, wherein the surface portion of the contact metal layer on the p-type semiconductor layer side includes a semiconductor-metal-containing layer that contains a Group III metal.

9. A gallium nitride compound semiconductor light-emitting device according to claim 8, wherein the semiconductor-metal-containing layer further contains a nitrogen atom.

10. A gallium nitride compound semiconductor light-emitting device according to claim 8, wherein the semiconductor-metal-containing layer has a thickness of 0.1 to 3 nm.

11. A gallium nitride compound semiconductor light-emitting device according to claim 8, wherein the semiconductor-metal-containing layer contains a Group III metal at a concentration of 0.1 to 50 at. % with respect to the total amount of metal atoms contained in the semiconductor-metal-containing layer.

12. A gallium nitride compound semiconductor light-emitting device according to claim 1, wherein the contact metal layer comprises Pt.

13. A gallium nitride compound semiconductor light-emitting device according to claim 12, wherein the contact metal layer has a Pt(222) plane spacing of 1.130 Å or less.

14. A gallium nitride compound semiconductor light-emitting device according to claim 1, wherein the contact metal layer is formed through RF discharge sputtering.

15. A gallium nitride compound semiconductor light-emitting device according to claim 4, wherein the contact metal layer is formed through RF discharge sputtering, and the reflecting layer is formed through DC discharge sputtering.

16. A method for producing a gallium nitride compound semiconductor light-emitting device according to claim 1, wherein the gallium nitride compound semiconductor light-emitting device is maintained at a temperature of 350° C. or less after a step of forming the contact metal layer.
